(19) United States
(12) Patent Application Publication
(10) Pub. No.: US 2024/0128932 A1
(43) Pub. Date: Apr. 18, 2024

(54) POWER AMPLIFIER CIRCUIT AND POWER AMPLIFICATION METHOD

(71) Applicant: Murata Manufacturing Co., Ltd., Nagaokakyo-shi (JP)

(72) Inventors: Kenji TAHARA, Nagaokakyo-shi (JP); Yoshiaki SUKEMORI, Nagaokakyo-shi (JP); Kae YAMAMOTO, Nagaokakyo-shi (JP); Ryo WAKABAYASHI, Nagaokakyo-shi (JP)

(73) Assignee: Murata Manufacturing Co., Ltd., Nagaokakyo-shi (JP)

(21) Appl. No.: 18/395,786

(22) Filed: Dec. 26, 2023

Related U.S. Application Data
(63) Continuation of application No. PCT/JP2022/022395, filed on Jun. 1, 2022.

(30) Foreign Application Priority Data
Jul. 7, 2021 (JP) 2021-112752

(51) Int. Cl. H03F 1/02; H03F 3/195; H03F 3/24; H03F 3/72

(52) U.S. Cl. CPC H03F 1/0222; H03F 3/195; H03F 3/245; H03F 3/72; H03F 2200/102; H03F 2200/423; H03F 2200/451; H03F 2203/7215

(57) ABSTRACT

A power amplifier circuit includes external input and output terminals; a first power amplifier with first input and output terminals, the first input terminal being connected to the external input terminal, the first output terminal being connected to the external output terminal; a second power amplifier having second input and output terminals, the second input terminal being connected to the external input terminal, the second output terminal being connected to the external output terminal; a power supply terminal that receives a power supply voltage that is supplied to the first power amplifier and controllably supplied to the second power amplifier; and a switch having first and second terminals, the first terminal being connected to the power supply terminal, the second terminal being connected to the second power amplifier.

### CROSS-REFERENCE TO RELATED APPLICATIONS

The present application is a continuation of international application no. PCT/JP2022/022395 filed Jun. 1, 2022, which claims priority to Japanese application JP 2021-112752, filed Jul. 7, 2021, the entire contents of each of which being incorporated herein by reference.

### TECHNICAL FIELD

The present disclosure relates to a power amplifier circuit and a power amplification method.

### BACKGROUND ART

These days, power amplification efficiency is improving by the application of an envelope tracking (ET) mode to a power amplifier circuit. Additionally, a technology for supplying a power supply voltage of multiple discrete voltage levels in the ET mode is disclosed (see Patent Document 1, for example).

### CITATION LIST

### Patent Document

Patent Document 1: U.S. Pat. No. 8,829,993

### SUMMARY

### Technical Problems

However, among other things, the supplying of a power supply voltage of multiple discrete voltage levels to a power amplifier circuit, as disclosed in Patent Document 1, may decrease the efficiency.

It is an aspect of the present disclosure to provide a power amplifier circuit and a power amplification method that can regulate a decrease in efficiency, which is caused by a power supply voltage of multiple discrete voltage levels.

### Solution to Problems

A power amplifier circuit according to an aspect of the disclosure includes external input and output terminals; a first power amplifier with first input and output terminals, the first input terminal being connected to the external input terminal, the first output terminal being connected to the external output terminal; a second power amplifier having second input and output terminals, the second input terminal being connected to the external input terminal, the second output terminal being connected to the external output terminal; a power supply terminal that receives a power supply voltage that is supplied to the first power amplifier and controllably supplied to the second power amplifier; and a switch having first and second terminals, the first terminal being connected to the power supply terminal, the second terminal being connected to the second power amplifier.

A power amplification method according to an aspect of the disclosure includes amplifying a radio-frequency signal with a power supply voltage of a first voltage level by using a first power amplifier and a second power amplifiers under a condition a power supply voltage of the first voltage level is supplied to a power supply terminal and in response to receiving a first control signal indicating that the second power amplifier is also to be used to amplify the radio-frequency signal; amplifying the radio-frequency signal with the power supply voltage of the first voltage level by using the first power amplifier under the condition the power supply voltage of the first voltage level is supplied to the power supply terminal and in response to receiving a second control signal indicating that the second power amplifier is not to be used to amplify the radio-frequency signal; and amplifying the radio-frequency signal with a power supply voltage of a second voltage level, the second voltage level being lower than the first voltage level, by using the first power amplifier and the second power amplifier under another condition that the power supply voltage of the second voltage level is supplied to the power supply terminal and in response to receiving the first control signal.

A power amplification method according to an aspect of the disclosure includes amplifying a radio-frequency signal with a power supply voltage of a first voltage level by using a first power amplifier under a condition the power supply voltage of the first voltage level is supplied to a power supply terminal and in response to receiving a second control signal indicating that a second power amplifier is not to be used to amplify a radio-frequency signal; amplifying a radio-frequency signal with a power supply voltage of a second voltage level, the second voltage level being lower than the first voltage level, by using the first and second power amplifiers under another condition that a power supply voltage of the second voltage level is supplied to the power supply terminal and in response to receiving a first control signal indicating that the second power amplifier is to be used to amplify the radio-frequency signal; and amplifying the radio-frequency signal with a power supply voltage of the second voltage level by using the first power amplifier under a third condition of a power supply voltage of the second voltage level being supplied to the power supply terminal and in response to receiving the second control signal.

### Advantageous Effects

Using a power amplifier circuit according to an aspect of the disclosure can regulate a decrease in efficiency, which is caused by a power supply voltage of multiple discrete voltage levels.

### BRIEF DESCRIPTION OF DRAWINGS

FIG. 1 is a circuit diagram of a power amplifier circuit, a radio-frequency circuit, and a communication device according to an embodiment.

FIG. 2A is a graph illustrating an example of the transition of a power supply voltage in a digital ET mode.

FIG. 2B is a graph illustrating an example of the transition of a power supply voltage in an analog ET mode.

FIG. 2C is a graph illustrating an example of the transition of a power supply voltage in an APT (Average Power Tracking) mode.

FIG. 3 is a sequence diagram illustrating an operation of the communication device according to the embodiment.

FIG. 4 is a graph illustrating the efficiency when a switch is maintained in the OFF state in the power amplifier circuit of the embodiment.

FIG. 5 is a graph illustrating the efficiency when the switch is maintained in the ON state in the power amplifier circuit of the embodiment.

FIG. 6 is a graph illustrating the efficiency when the switch is changed between the ON state and the OFF state in the power amplifier circuit of the embodiment.

FIG. 7 is a plan view of a radio-frequency module according to a first example.

FIG. 8 is a plan view of the radio-frequency module according to the first example.

FIG. 9 is a sectional view of the radio-frequency module according to the first example.

FIG. 10 is a plan view of a power amplifier module according to a second example.

FIG. 11 is a plan view of the power amplifier module according to the second example.

FIG. 12 is a sectional view of the power amplifier module according to the second example.

FIG. 13 is a circuit diagram of a power amplifier circuit according to a modified example.

### DESCRIPTION OF EMBODIMENTS

Embodiments will be described below in detail with reference to the drawings. All the embodiments described below illustrate general or specific examples. Numerical values, configurations, materials, elements, and positions and connection states of the elements illustrated in the following embodiments are only examples and are not intended to limit the invention, as claimed in the appended claims.

The drawings are only schematically shown and are not necessarily precisely illustrated. For the sake of clarity of the disclosed embodiments, as needed, the drawings are illustrated in an exaggerated manner or with omissions and the ratios of elements in the drawings are adjusted. The shapes, positional relationships, and ratios of elements in the drawings may be different from those of the actual elements. In the drawings, substantially identical elements are designated by like reference numeral and an explanation of such elements may be omitted or be merely simplified from the second time.

In the individual drawings, the x axis and the y axis are axes which are perpendicular to each other on a plane parallel with the main surfaces of a module laminate. More specifically, if the module laminate has a rectangular shape in a plan view, the x axis is parallel with a first side of the module laminate, while the y axis is parallel with a second side perpendicular to the first side of the module laminate. The z axis is an axis perpendicular to the main surfaces of the module laminate. The positive-side direction of the z axis is the upward direction, while the negative-side direction of the z axis is the downward direction.

In the circuit configurations of the disclosure, “A is connected to B” includes, not only the meaning that A is directly connected to B using a connection terminal and/or a wiring conductor, but also the meaning that A is electrically connected to B via another circuit element. “An element is connected between A and B” means that the element is connected to both A and B between A and B and includes the meaning that the element is connected in series with a path connecting A and B and also that the element is parallel-connected (shunt-connected) between this path and a ground.

In the layout of components of the disclosure, “in a plan view” means that an object is orthographically projected on an xy plane from the positive side of the z axis and is viewed from this side. “A overlaps or matches B in a plan view” means that a region of A orthographically projected on the xy plane overlaps or matches a region of B orthographically projected on the xy plane. “A is disposed between B and C” means that at least one of line segments connecting a certain point within B and a certain point within C passes through A. “A is disposed closer to C than B is” means that the shortest distance between A and C is shorter than that between B and C. Terms representing the relationship between elements, such as “being parallel” and “being vertical”, terms representing the shape of an element, such as “being rectangular”, and ranges of numerical values are not necessarily to be interpreted in an exact sense, but to be interpreted in a broad sense. That is, such terms and ranges also cover substantially equivalent ranges, such as about several percent of allowance.

### EMBODIMENTS

### [1 Circuit Configurations of Communication Device 6, Radio-Frequency Circuit 1, and Power Amplifier Circuit 10]

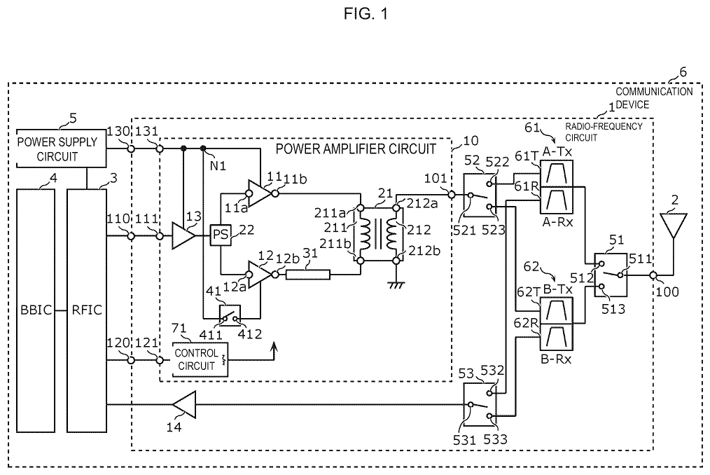

The circuit configurations of a communication device 6, a radio-frequency circuit 1, and a power amplifier circuit 10 according to the embodiment will be described below with reference to FIG. 1. FIG. 1 is a circuit diagram of the power amplifier circuit 10, the radio-frequency circuit 1, and the communication device 6 according to the embodiment.

### [1.1 Circuit Configuration of Communication Device 6]

The circuit configuration of the communication device 6 will first be described below. As illustrated in FIG. 1, the communication device 6 according to the embodiment includes a radio-frequency circuit 1, an antenna 2, an RFIC (Radio Frequency Integrated Circuit) 3, a BBIC (Baseband Integrated Circuit) 4, and a power supply circuit 5.

The radio-frequency circuit 1 transfers a radio-frequency signal between the antenna 2 and the RFIC 3. The internal configuration of the radio-frequency circuit 1 will be discussed later.

The antenna 2 is connected to an antenna connection terminal 100 of the radio-frequency circuit 1 and transmits a radio-frequency signal output from the radio-frequency circuit 1.

The RFIC 3 is an example of a signal processing circuit that processes a radio-frequency signal. The RFIC 3 will be explained below more specifically. The RFIC 3 performs signal processing, such as down-conversion, on a radio-frequency reception signal, which is received via a receive path of the radio-frequency circuit 1, and outputs the resulting reception signal to the BBIC 4. The RFIC 3 also performs signal processing, such as up-conversion, on a transmission signal output from the BBIC 4 and outputs the resulting radio-frequency transmission signal to the transmit path of the radio-frequency circuit 1. The RFIC 3 includes a controller that controls the radio-frequency circuit 1 and the power supply circuit 5. All or some of the functions of the RFIC 3 as the controller may be disposed outside the RFIC 3, such as in the BBIC 4 or the radio-frequency circuit 1.

The BBIC 4 is a baseband signal processing circuit that performs signal processing by using an intermediate frequency band, which is lower than a radio-frequency signal transferred by the radio-frequency circuit 1. Examples of signals to be processed by the BBIC 4 are image signals for displaying images and/or audio signals for performing communication via a speaker.

The power supply circuit 5 is a digital envelope tracker that is able to supply a power supply voltage of multiple discrete voltage levels. More specifically, in accordance with a control signal from the RFIC 3, the power supply circuit 5 can supply a power supply voltage of multiple discrete voltage levels that track the envelope of a radio-frequency signal. For example, the power supply circuit 5 presets a power supply voltage of multiple discrete voltage levels and selects one of the preset voltage levels by using a switch (not shown) and outputs the selected voltage level. The power supply circuit 5 can thus implement high-speed switching using the switch to change the level of the power supply voltage to be supplied to the power amplifier circuit 10. Instead of presetting multiple voltage levels and selecting and outputting a voltage level by using the switch, the power supply circuit 5 may obtain multiple voltage levels in a different manner. For example, when necessary, the power supply circuit 5 may generate a voltage level, which is a voltage level selected from multiple discrete voltage levels, and output the generated voltage level.

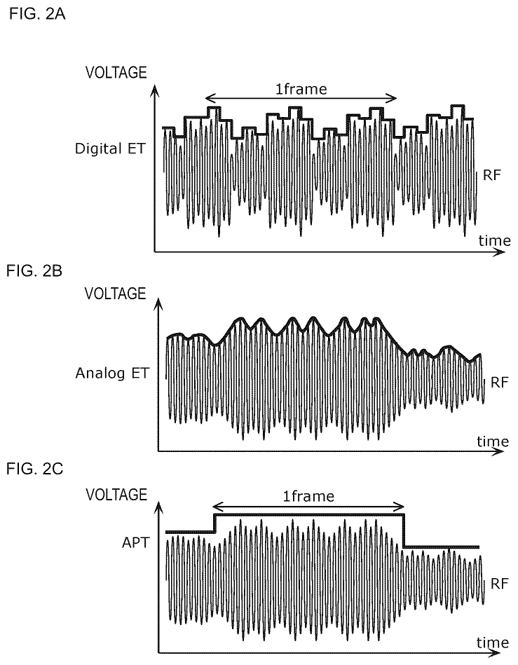

Hereinafter, tracking the envelope of a radio-frequency signal using multiple discrete voltage levels will be called digital envelope tracking (hereinafter called digital ET), and a mode in which digital ET is applied to a power supply voltage will be called a digital ET mode. The digital ET mode will be explained later with reference to FIGS. 2A through 2C.

The circuit configuration of the communication device 6 shown in FIG. 1 is an example and does not restrict the configuration of the communication device 6. In one example, the provision of the antenna 2 and/or the BBIC 4 in the communication device 6 may be omitted. In another example, the communication device 6 may include plural antennas.

### [1.2 Circuit Configuration of Radio-Frequency Circuit 1]

The circuit configuration of the radio-frequency circuit 1 will now be described below. As illustrated in FIG. 1, the radio-frequency circuit 1 includes a power amplifier circuit 10, a low-noise amplifier (LNA) 14, switches (SWs) 51 through 53, duplexers 61 and 62, an antenna connection terminal 100, an external input terminal 110, a control terminal 120, and a power supply terminal 130. Elements of the radio-frequency circuit 1 will be sequentially explained below.

The antenna connection terminal 100 is connected inside the radio-frequency circuit 1 to the switch 51 and is connected outside the radio-frequency circuit 1 to the antenna 2. Transmission signals of band A and band B amplified by the power amplifier circuit 10 are output to the antenna 2 via the antenna connection terminal 100. Reception signals of band A and band B received by the antenna 2 are input into the radio-frequency circuit 1 via the antenna connection terminal 100.

The external input terminal 110 is a terminal for receiving transmission signals of band A and band B from the outside of the radio-frequency circuit 1. The external input terminal 110 is connected outside the radio-frequency circuit 1 to the RFIC 3 and is connected inside the radio-frequency circuit 1 to the power amplifier circuit 10. With this configuration, transmission signals of band A and band B received from the RFIC 3 via the external input terminal 110 are supplied to the power amplifier circuit 10.

The control terminal 120 is a terminal for transferring a control signal. That is, the control terminal 120 is a terminal for receiving a control signal from the outside of the radio-frequency circuit 1 and/or a terminal for supplying a control signal to the outside of the radio-frequency circuit 1. A control signal is a signal for controlling electronic circuits included in the radio-frequency circuit 1. More specifically, a control signal is a digital signal for controlling power amplifiers 11 through 13 and a switch 41, for example.

The power supply terminal 130 is a terminal for receiving a power supply voltage from the power supply circuit 5. The power supply terminal 130 is connected outside the radio-frequency circuit 1 to the power supply circuit 5 and is connected inside the radio-frequency circuit 1 to the power amplifier circuit 10. With this configuration, a power supply voltage received from the power supply circuit 5 via the power supply terminal 130 is supplied to the power amplifier circuit 10.

The power amplifier circuit 10 can amplify transmission signals of band A and band B. The internal configuration of the power amplifier circuit 10 will be discussed later.

The switch 51 is connected between the antenna connection terminal 100 and the duplexers 61 and 62. The switch 51 has terminals 511 through 513. The terminal 511 is connected to the antenna connection terminal 100. The terminal 512 is connected to the duplexer 61. The terminal 513 is connected to the duplexer 62.

With this connection configuration, the switch 51 can connect the terminal 511 to one of the terminals 512 and 513 based on a control signal from the RFIC 3, for example. That is, the switch 51 can selectively connect the antenna connection terminal 100 to one of the duplexers 61 and 62. The switch 51 is constituted by an SPDT (Single-Pole Double-Throw) switch circuit, for example.

The switch 52 is connected between transmit filters 61T and 62T and the power amplifier circuit 10. The switch 52 has terminals 521 through 523. The terminal 521 is connected to the power amplifier circuit 10. The terminal 522 is connected to the transmit filter 61T. The terminal 523 is connected to the transmit filter 62T.

With this connection configuration, the switch 52 can connect the terminal 521 to one of the terminals 522 and 523, based on a control signal from the RFIC 3, for example. That is, the switch 52 can selectively connect the power amplifier circuit 10 to one of the transmit filters 61T and 62T. The switch 52 is constituted by an SPDT switch circuit, for example.

The switch 53 is connected between receive filters 61R and 62R and the low-noise amplifier 14. The switch 53 has terminals 531 through 533. The terminal 531 is connected to the low-noise amplifier 14. The terminal 532 is connected to the receive filter 61R. The terminal 533 is connected to the receive filter 62R.

With this connection configuration, the switch 53 can connect the terminal 531 to one of the terminals 532 and 533, based on a control signal from the RFIC 3, for example. That is, the switch 53 can selectively connect the low-noise amplifier 14 to one of the receive filters 61R and 62R. The switch 53 is constituted by an SPDT switch circuit, for example.

The duplexer 61 has a pass band including band A. The duplexer 61 includes the transmit filter 61T and the receive filter 61R and enables frequency division duplex (FDD) in band A.

The transmit filter 61T (A-Tx) is connected between the power amplifier circuit 10 and the antenna connection terminal 100. More specifically, one end of the transmit filter 61T is connected to the power amplifier circuit 10 via the switch 52, while the other end of the transmit filter 61T is connected to the antenna connection terminal 100 via the switch 51. The transmit filter 61T has a pass band including the uplink operating band of band A. The transmit filter 61T can thus allow, among transmission signals amplified by the power amplifier circuit 10, a transmission signal of band A to pass therethrough.

The receive filter 61R (A-Rx) is connected between the low-noise amplifier 14 and the antenna connection terminal 100. More specifically, one end of the receive filter 61R is connected to the antenna connection terminal 100 via the switch 51, while the other end of the receive filter 61R is connected to the low-noise amplifier 14 via the switch 53. The receive filter 61R has a pass band including the downlink operating band of band A. The receive filter 61R can thus allow, among reception signals received by the antenna 2, a reception signal of band A to pass therethrough.

The duplexer 62 has a pass band including band B. The duplexer 62 includes the transmit filter 62T and the receive filter 62R and enables FDD in band B.

The transmit filter 62T (B-Tx) is connected between the power amplifier circuit 10 and the antenna connection terminal 100. More specifically, one end of the transmit filter 62T is connected to the power amplifier circuit 10 via the switch 52, while the other end of the transmit filter 62T is connected to the antenna connection terminal 100 via the switch 51. The transmit filter 62T has a pass band including the uplink operating band of band B. The transmit filter 62T can thus allow, among transmission signals amplified by the power amplifier circuit 10, a transmission signal of band B to pass therethrough.

The receive filter 62R (B-Rx) is connected between the low-noise amplifier 14 and the antenna connection terminal 100. More specifically, one end of the receive filter 62R is connected to the antenna connection terminal 100 via the switch 51, while the other end of the receive filter 62R is connected to the low-noise amplifier 14 via the switch 53. The receive filter 62R has a pass band including the downlink operating band of band B. The receive filter 62R can thus allow, among reception signals received by the antenna 2, a reception signal of band B to pass therethrough.

Band A and band B are frequency bands used for a communication system to be constructed using a radio access technology (RAT). Band A and band B are predefined by a standardizing body (such as 3GPP (registered trademark) (3rd Generation Partnership Project) and IEEE (Institute of Electrical and Electronics Engineers). Examples of the communication system are a 5GNR system, an LTE system, and a WLAN (Wireless Local Area Network) system.

The radio-frequency circuit 1 shown in FIG. 1 is an example and does not restrict the configuration of the radio-frequency circuit 1. In one example, the provision of the duplexer 62 and the switches 51 through 53 in the radio-frequency circuit 1 may be omitted. Additionally, the provision of the receive path and the low-noise amplifier 14 and the receive filter 61R in the radio-frequency circuit 1 may be omitted. In another example, the radio-frequency circuit 1 may include a filter and a power amplifier circuit supporting band C, which is different from band A and band B.

### [1.3 Circuit Configuration of Power Amplifier Circuit 10]

The circuit configuration of the power amplifier circuit 10 will now be described below. As illustrated in FIG. 1, the power amplifier circuit 10 includes power amplifiers (PAs) 11 through 13, a transformer 21, a phase shifter (PS) 22, a transmission line 31, a switch (SW) 41, a control circuit (power amplifier controller (PAC)) 71, an external input terminal 111, an external output terminal 101, a control terminal 121, and a power supply terminal 131. Elements of the power amplifier circuit 10 will be sequentially explained below.

The external input terminal 111 is a terminal for receiving transmission signals of band A and band B from the outside of the power amplifier circuit 10. The external input terminal 111 is connected outside the power amplifier circuit 10 to the RFIC 3 via the external input terminal 110 and is connected inside the power amplifier circuit 10 to the power amplifier 13. With this configuration, transmission signals of band A and band B received from the RFIC 3 via the external input terminal 111 are supplied to the power amplifier 13. The external input terminal 111 may be integrated with the external input terminal 110.

The control terminal 121 is a terminal for transferring a control signal. That is, the control terminal 121 is a terminal for receiving a control signal from the outside of the power amplifier circuit 10 and/or a terminal for supplying a control signal to the outside of the power amplifier circuit 10. The control terminal 121 may be integrated with the control terminal 120.

The power supply terminal 131 is a terminal for receiving a power supply voltage from the power supply circuit 5. The power supply terminal 131 is connected outside the power amplifier circuit 10 to the power supply circuit 5 via the power supply terminal 130 and is connected inside the power amplifier circuit 10 to the power amplifiers 11 through 13. With this configuration, a power supply voltage received from the power supply circuit 5 via the power supply terminal 131 is supplied to the power amplifiers 11 through 13. The power supply terminal 131 may be integrated with the power supply terminal 130.

The power amplifier 13 is connected between the external input terminal 111 and the power amplifiers 11 and 12. More specifically, the input terminal of the power amplifier 13 is connected to the external input terminal 111, while the output terminal of the power amplifier 13 is connected to the power amplifiers 11 and 12 via the phase shifter 22.

With this connection configuration, the power amplifier 13 can amplify transmission signals of band A and band B received via the external input terminal 111 by using a power supply voltage received via the power supply terminal 131. The power amplifier 13 forms the input stage (drive stage) of a multistage amplifier circuit.

The phase shifter 22 is connected between the power amplifier 13 and the power amplifiers 11 and 12. More specifically, the input terminal of the phase shifter 22 is connected to the power amplifier 13, while one output terminal of the phase shifter 22 is connected to the power amplifier 11 and the other output terminal is connected to the power amplifier 12.

With this connection configuration, the phase shifter 22 can distribute a signal amplified by the power amplifier 13 and output the resulting two signals to the power amplifiers 11 and 12. When distributing a signal, the phase shifter 22 can adjust the phase of the two distributed signals. For example, the phase shifter 22 shifts by −90 degrees (delays by 90 degrees) the signal to be output to the power amplifier 11 with respect to the signal to be output to the power amplifier 12. The phase adjustment to be made by the phase shifter 22 is not limited to this example. For instance, the phase shifter 22 may suitably change the phase difference of the two distributed signals based on the internal configuration of the power amplifier circuit 10.

The power amplifier 11 is an example of a first power amplifier and is connected between the external input terminal 111 and the external output terminal 101. More specifically, the power amplifier 11 has an input terminal 11a and an output terminal 11b. The input terminal 11a is an example of a first input terminal and is connected to the external input terminal 111 via the phase shifter 22 and the power amplifier 13. The output terminal 11b is an example of a first output terminal and is connected to the external output terminal 101 via the transformer 21. The power amplifier 11 is connected to the external output terminal 101 without having the power amplifier 12 interposed therebetween. That is, the power amplifiers 11 and 12 are connected in parallel with each other.

With this connection configuration, the power amplifier 11 can amplify transmission signals of band A and band B amplified by the power amplifier 13 by using a power supply voltage received via the power supply terminal 131. As the power amplifier 11, a Class AB amplifier, for example, is used, and the power amplifier 11 forms the output stage (power stage) of the multistage amplifier circuit, together with the power amplifier 12. The power amplifier 11 is not restricted to a Class AB amplifier. A Class A amplifier, for example, may be used as the power amplifier 11.

The power amplifier 12 is an example of a second power amplifier and is connected between the external input terminal 111 and the external output terminal 101. More specifically, the power amplifier 12 has an input terminal 12a and an output terminal 12b. The input terminal 12a is an example of a second input terminal and is connected to the external input terminal 111 via the phase shifter 22 and the power amplifier 13. The output terminal 12b is an example of a second output terminal and is connected to the transformer 21 via the transmission line 31. The power amplifier 12 is connected to the external output terminal 101 without having the power amplifier 11 interposed therebetween. That is, the power amplifiers 11 and 12 are connected in parallel with each other.

With this connection configuration, the power amplifier 12 can amplify transmission signals of band A and band B amplified by the power amplifier 13 by using a power supply voltage received via the power supply terminal 131 and the switch 41. As the power amplifier 12, a Class AB amplifier, for example, is used, and the power amplifier 12 forms the output stage (power stage) of the multistage amplifier circuit, together with the power amplifier 11. The power amplifier 12 is not restricted to a Class AB amplifier. A Class C amplifier, for example, may be used as the power amplifier 12.

The switch 41 is connected between the power supply terminal 131 and the power amplifier 12. More specifically, the switch 41 has terminals 411 and 412. The terminal 411 is an example of a first terminal and is connected to the power supply terminal 131 via a node N1. The terminal 412 is an example of a second terminal and is connected to the power amplifier 12. The node N1 is a branch point between a path which connects the power supply terminal 131 and the power amplifier 11 and a path which connects the power supply terminal 131 and the power amplifier 12.

With this connection configuration, the switch 41 can connect the terminal 411 to the terminal 412. That is, the switch 41 can switch between ON and OFF of the path connecting the power supply terminal 131 and the power amplifier 12. The switch 41 is constituted by an SPST (Single-Pole Single-Throw) switch circuit, for example.

The transmission line 31 is a ¼-wavelength transmission line, for example, and can rotate the load impedance by 180 degrees on a Smith chart. The transmission line 31 may also be called a phase adjuster or a phase shifter. The length of the transmission line 31 is determined based on band A and band B. The transmission line 31 is connected between the output terminal 12b of the power amplifier 12 and an end 211b of an input coil 211 of the transformer 21. With this connection configuration, the transmission line 31 can shift by −90 degrees (delay by 90 degrees) the phase of transmission signals of band A and band B amplified by the power amplifier 12. The transmission line 31 may include at least one of an inductor and a capacitor. This can reduce the length of the transmission line 31.

The transformer 21 includes an input coil 211 and an output coil 212. One end 211a of the input coil 211 is connected to the output terminal 11b of the power amplifier 11, while the other end 211b of the input coil 211 is connected to the output terminal 12b of the power amplifier 12 via the transmission line 31. One end 212a of the output coil 212 is connected to the external output terminal 101, while the other end 212b of the output coil 212 is connected to a ground.

With this connection configuration, the transformer 21 can combine a transmission signal amplified by the power amplifier 11 and a transmission signal amplified by the power amplifier 12 and output the combined transmission signal to the external output terminal 101. The transformer 21 can also output a transmission signal amplified by the power amplifier 11 to the external output terminal 101.

The external output terminal 101 is a terminal for supplying transmission signals of band A and band B amplified by the power amplifier circuit 10 to the outside of the power amplifier circuit 10. The external output terminal 101 is connected inside the power amplifier circuit 10 to the transformer 21 and is connected outside the power amplifier circuit 10 to the switch 52. With this configuration, transmission signals supplied via the external output terminal 101 are transferred to the antenna connection terminal 100 via the transmit filters 61T and 62T.

The control circuit 71 controls the power amplifiers 11 through 13 and the switch 41. For example, the control circuit 71 receives a control signal from the RFIC 3 and outputs the control signal to the power amplifiers 11 through 13 and the switch 41. The control circuit 71 may control other circuit components (switches 51 through 53, for example). The control circuit 71 may be included in each of the power amplifier circuit 10 and the radio-frequency circuit 1. The provision of the control circuit 71 in the power amplifier circuit 10 may be omitted. The control circuit 71 is shown with a single output arrow. This is intended to show that the control circuit 71 can control each of the components discussed above, and may be connected by separate conductors (not shown).

The circuit configuration of the power amplifier circuit 10 shown in FIG. 1 is an example and does not restrict the configuration of the power amplifier circuit 10. In one example, the provision of the transformer 21 in the power amplifier circuit 10 may be omitted and the transmission line 31 may be connected to the output terminal 11b of the power amplifier 11. In another example, the provision of the transmission line 31 in the power amplifier circuit 10 may be omitted. In another example, the provision of the power amplifier 13 in the power amplifier circuit 10 may be omitted. In another example, the power amplifier circuit 10 may be a differential composition amplifier circuit. In this case, the phase shifter 22 may be constituted by a transformer, for example, and adjust the phase difference of two distributed signals to 180 degrees. In another example, the provision of the phase shifter 22 in the power amplifier 10 may be omitted.

In addition to the switch 41, the power amplifier circuit 10 may include a switch connected between the power supply terminal 131 and the power amplifier 11. This makes it also possible to switch between ON and OFF of the path connecting the power supply terminal 131 and the power amplifier 11.

### [2 Explanation of Digital ET Mode]

The digital ET mode will be explained below with reference to FIGS. 2A through 2C by comparison with a known ET mode (hereinafter called the analog ET mode) and an APT mode. FIG. 2A is a graph illustrating an example of the transition of a power supply voltage in the digital ET mode. FIG. 2B is a graph illustrating an example of the transition of a power supply voltage in the analog ET mode. FIG. 2C is a graph illustrating an example of the transition of a power supply voltage in the APT mode. In FIGS. 2A through 2C, the horizontal axis indicates the time, and the vertical axis indicates the voltage. The thick solid line represents the power supply voltage, while the thin solid line (waveform) represents a modulated signal.

In the digital ET mode, as shown in FIG. 2A, the power supply voltage is varied to multiple discrete voltage levels within one frame so as to track the envelope of the modulated signal. As a result, the power supply voltage signal forms a rectangular wave. In this context “rectangular wave” means a waveform with discrete steps in voltage levels. In the digital ET mode, based on an envelope signal, the level of a power supply voltage is selected or set from among multiple discrete voltage levels.

A frame is a unit of time which is a feature that contributes to a characterization of a radio-frequency signal (modulated signal). For example, 5GNR (5th Generation New Radio) and LTE (Long Term Evolution) define that a frame includes ten subframes, each subframe includes plural slots, and each slot is constituted by plural symbols. The subframe length is 1 ms, and the frame length is 10 ms.

In the analog ET mode, as shown in FIG. 2B, the power supply voltage is continuously varied so as to track the envelope of the modulated signal. In the analog ET mode, the power supply voltage is determined based on an envelope signal. In the analog ET mode, if the envelope of a modulated signal fluctuates at high speed, it is difficult for a power supply voltage to track the envelope of the modulated signal.

In the APT mode, as shown in FIG. 2C, based on average power, the power supply voltage is varied to multiple discrete voltage levels in units of frames. As a result, the power supply voltage signal forms a rectangular wave. In the APT mode, the level of a power supply voltage is determined, not based on an envelope signal, but based on average output power. In the APT mode, the voltage level may be varied in a unit smaller than a frame (subframe, for example).

### [3 Operation of Communication Device 6]

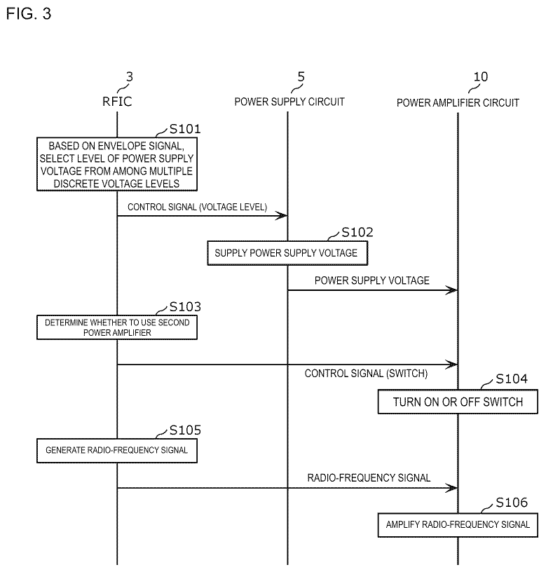

The operation of the communication device 6 according to the embodiment will now be described below with reference to FIG. 3. FIG. 3 is a sequence diagram illustrating the operation of the communication device 6 according to the embodiment.

Based on an envelope signal, from among multiple discrete voltage levels, the RFIC 3 selects or sets the level of a power supply voltage to be used in the power amplifier circuit 10 (S101). The RFIC 3 selects or sets the level of the power supply voltage so as to track the envelope of a carrier wave modulated based on transmission information (hereinafter such a carrier wave will be called “modulated signal” or “radio-frequency signal”). This will be explained more specifically. The RFIC 3 obtains the envelope value of each symbol, for example. The RFIC 3 then, for example, refers to a range of envelope values associated with each of the multiple discrete voltage levels and selects or sets the voltage level corresponding to the obtained envelope value. A control signal indicating the voltage level set or selected in this manner is output to the power supply circuit 5.

The envelope signal is a signal indicating the envelope of a modulated signal. The envelope value is represented by a square root of (I²+Q²), for example. (I, Q) is a constellation point, with I being an in-phase signal component, and Q being a quadrature component. The constellation point is a point of a signal modulated by digital modulation on a constellation diagram. (I, Q) is determined by the BBIC 4 based on transmission information, for example.

The power supply circuit 5 supplies a power supply voltage of the selected or set voltage level to the power amplifier circuit 10 in accordance with a control signal from the RFIC 3 (S102). For example, the power supply circuit 5 generates a reference voltage level based on an input voltage output from an external power supply and generates multiple discrete voltage levels from the reference voltage level. Then, by controlling a switch in accordance with the control signal from the RFIC 3, the power supply circuit 5 selects one of the generated multiple discrete voltage levels and outputs a power supply voltage of the selected voltage level to the power amplifier circuit 10.

Based on the envelope signal of a radio-frequency signal, the RFIC 3 determines whether to use the power amplifier 12 to amplify the radio-frequency signal (S103). That is, the RFIC 3 determines whether to use both of the power amplifiers 11 and 12 or to use only the power amplifier 11 to amplify the radio-frequency signal.

This will be discussed more specifically. The RFIC 3 determines whether, when a first voltage level is selected or set, the envelope value of a radio-frequency signal is greater than or equal to a first predetermined value. As a term on convenience, the term “when” is often used herein as an event that has actually occurred. Similarly, the term “if” is often used to describe a status of a circuitry or waveform of several possible status conditions. If the envelope value of the radio-frequency signal is greater than or equal to the first predetermined value, the RFIC 3 determines that the power amplifier 12 is to be used. If the envelope value of the radio-frequency signal is smaller than the first predetermined value, the RFIC 3 determines that the power amplifier 12 is not to be used. The RFIC 3 also determines whether, when a second voltage level, which is lower than the first voltage level, is selected or set, the envelope value of the radio-frequency signal is greater than or equal to a second predetermined value, which is smaller than the first predetermined value. If the envelope value of the radio-frequency signal is greater than or equal to the second predetermined value, the RFIC 3 determines that the power amplifier 12 is to be used. If the envelope value of the radio-frequency signal is smaller than the second predetermined value, the RFIC 3 determines that the power amplifier 12 is not to be used.

The RFIC 3 then sends a control signal indicating the determination result to the power amplifier circuit 10. This will be discussed more specifically. If it is determined that the power amplifier 12 is to be used, the RFIC 3 sends a first control signal to the power amplifier circuit 10. The first control signal indicates that the power amplifier 12 is to be used. That is, the first control signal indicates that both of the power amplifiers 11 and 12 are to be used to amplify a radio-frequency signal. If it is determined that the power amplifier 12 is not to be used, the RFIC 3 sends a second control signal to the power amplifier circuit 10. The second control signal indicates that the power amplifier 12 is not to be used. That is, the second control signal indicates that, not the power amplifier 12, but the power amplifier 11 is to be used to amplify a radio-frequency signal.

The control circuit 71 of the power amplifier circuit 10 controls ON/OFF of the switch 41 in accordance with the control signal received from the RFIC 3 via the control terminal 121 (S104). That is, upon receiving the first control signal indicating that the power amplifier 12 is to be used, the control circuit 71 connects the terminal 411 of the switch 41 to the terminal 412. In contrast, upon receiving the second control signal indicating that the power amplifier 12 is not to be used, the control circuit 71 does not connect the terminal 411 of the switch 41 to the terminal 412.

The RFIC 3 generates a radio-frequency signal and outputs it to the power amplifier circuit 10 (S105). The power amplifier circuit 10 amplifies the radio-frequency signal received from the RFIC 3 by using the power supply voltage supplied from the power supply circuit 5 (S106).

With the above-described operation, when a power supply voltage of the first voltage level is supplied to the power supply terminal 131 and when the first control signal is received, the power amplifier circuit 10 can amplify a radio-frequency signal with the power supply voltage of the first voltage level by using the power amplifiers 11 and 12. When a power supply voltage of the first voltage level is supplied to the power supply terminal 131 and when the second control signal is received, the power amplifier circuit 10 can amplify a radio-frequency signal with the power supply voltage of the first voltage level by using the power amplifier 11 but not using the power amplifier 12. When a power supply voltage of the second voltage level, which is lower than the first voltage level, is supplied to the power supply terminal 131 and when the first control signal is received, the power amplifier circuit 10 can amplify a radio-frequency signal with the power supply voltage of the second voltage level by using the power amplifiers 11 and 12. When a power supply voltage of the second voltage level is supplied to the power supply terminal 131 and when the second control signal is received, the power amplifier circuit 10 can amplify a radio-frequency signal with the power supply voltage of the second voltage level by using the power amplifier 11 but not using the power amplifier 12.

### [4 Relationship Between Output Power and Efficiency]

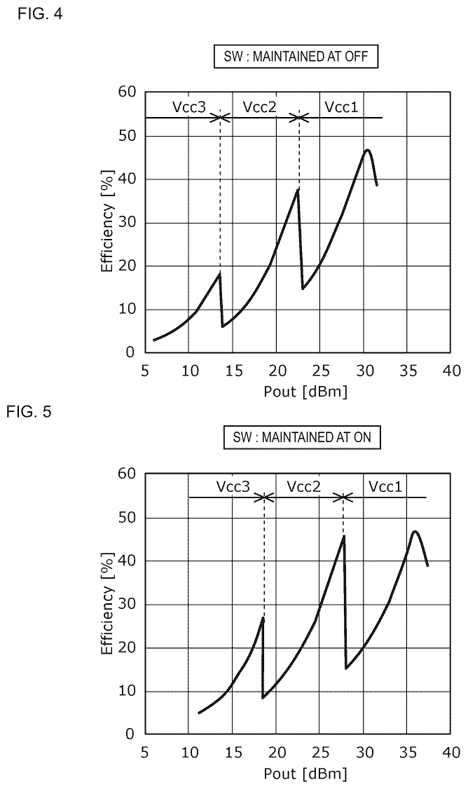

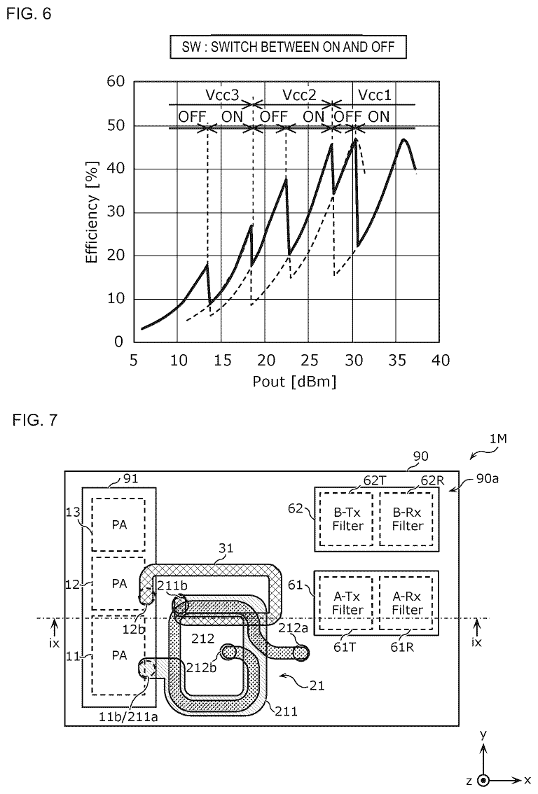

The relationship between output power and efficiency obtained by the above-described operation will now be discussed below with reference to FIGS. 4 through 6. FIG. 4 is a graph illustrating the efficiency when the switch 41 is maintained in the OFF state in the power amplifier circuit 10 of the embodiment. That is, the graph of FIG. 4 represents the efficiency obtained when a radio-frequency signal is amplified with multiple discrete voltage levels by using the power amplifier 11 but not using the power amplifier 12. FIG. 5 is a graph illustrating the efficiency when the switch 41 is maintained in the ON state in the power amplifier circuit 10 of the embodiment. That is, the graph of FIG. 5 represents the efficiency obtained when a radio-frequency signal is amplified with multiple discrete voltage levels by using the power amplifiers 11 and 12. FIG. 6 is a graph illustrating the efficiency when the switch 41 is changed between the ON state and the OFF state in the power amplifier circuit 10 of the embodiment. That is, the graph of FIG. 6 represents the efficiency obtained when the ON/OFF states of the power amplifier 12 are switched for each voltage level. In FIGS. 4 through 6, the horizontal axis indicates output power, and the vertical axis indicates efficiency. Vcc1 through Vcc3 represent the level of the power supply voltage, and the relationship in the magnitude of the voltage levels satisfies Vcc1>Vcc2>Vcc3. Vcc1 is an example of the first voltage level, and Vcc2 is an example of the second voltage level.

As shown in FIGS. 4 and 5, the output power obtained at the same level of the power supply voltage is smaller when the switch 41 is maintained in the OFF state (FIG. 4) than when the switch 41 is maintained in the ON state (FIG. 5). That is, the peak of efficiency with respect to the output voltage shifts more to the left side in FIG. 4 than that in FIG. 5. In other words, what is called “back-off”, is generated. The amount of back-off depends on the size of the power amplifier 12. For example, as the size of the power amplifier 12 is larger, the back-off becomes greater, and as the size of the power amplifier 12 is smaller, the back-off becomes smaller.

As is seen from FIGS. 4 and 5, when the level of the power supply voltage is fixed, the efficiency declines as output power decreases. To deal with this issue, the switch 41 of the power amplifier circuit 10 is changed between the ON state and the OFF state as stated above, thereby regulating a decline in efficiency accompanying decreased output power.

More specifically, when Vcc1 is supplied, if the envelope value is large, the switch 41 is turned ON and the power amplifier 12 is used, and if the envelope value is small, the switch 41 is turned OFF and the power amplifier 12 is not used. In this manner, when Vcc1 is supplied, the switch 41 is changed between the ON state and the OFF state in accordance with the envelope value. This can regulate a decline in efficiency accompanying decreased output power when Vcc1 is supplied, as shown in FIG. 6.

Likewise, when Vcc2 is supplied, if the envelope value is large, the switch 41 is turned ON and the power amplifier 12 is used, and if the envelope value is small, the switch 41 is turned OFF and the power amplifier 12 is not used. In this manner, when Vcc2 is supplied, the switch 41 is changed between the ON state and the OFF state in accordance with the envelope value. This can regulate a decline in efficiency accompanying decreased output power when Vcc2 is supplied, as shown in FIG. 6.

Likewise, when Vcc3 is supplied, if the envelope value is large, the switch 41 is turned ON and the power amplifier 12 is used, and if the envelope value is small, the switch 41 is turned OFF and the power amplifier 12 is not used. In this manner, when Vcc3 is supplied, the switch 41 is changed between the ON state and the OFF state in accordance with the envelope value. This can regulate a decline in efficiency accompanying decreased output power when Vcc3 is supplied, as shown in FIG. 6.

The above-described operation of the communication device 6 is an example and does not restrict the operation of the communication device 6. For instance, selecting or setting of the voltage level and determining whether to use the second power amplifier may be executed in one step.

### [5 Examples of Radio-Frequency Circuit 1 and Power Amplifier Circuit 10]

### [5.1 Radio-Frequency Module 1M]

As an example of the radio-frequency circuit 1 according to the above-described embodiment, a radio-frequency module 1M will be discussed below with reference to FIGS. 7 through 9.

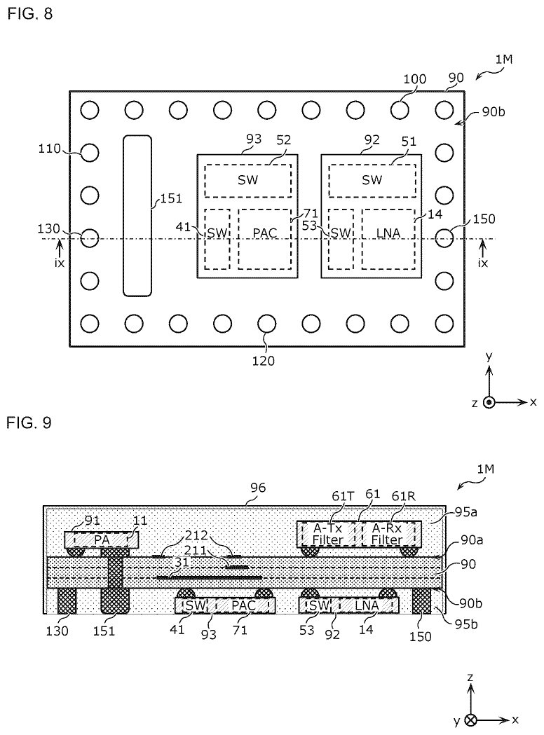

FIG. 7 is a plan view of the radio-frequency module 1M according to the present example when a main surface 90a of a module laminate 90 and the inside of the module laminate 90 are seen through from the positive side of the z axis. FIG. 8 is a plan view of the radio-frequency module 1M according to the present example when a main surface 90b of the module laminate 90 is seen through from the positive side of the z axis. FIG. 9 is a sectional view of the radio-frequency module 1M according to the present example. The cross section of the radio-frequency module 1M in FIG. 9 is a cross section taken along line ix-ix in FIGS. 7 and 8.

In FIGS. 7 through 9, for easy understanding of the positional relationships between the components, some components are appended with alphabetical characters representing the corresponding components. However, such alphabetical characters are not appended to the actual components. In FIGS. 7 through 9, wiring for connecting plural components arranged in or on the module laminate 90 is partially omitted. In FIGS. 7 and 8, resin members 95a and 95b for covering plural components and a shield electrode layer 96 for covering the surfaces of the resin members 95a and 95b are not shown.

In addition to the plural circuit components included in the radio-frequency circuit 1 shown in FIG. 1, the radio-frequency module 1M includes the module laminate 90, resin members 95a and 95b, shield electrode layer 96, plural post electrodes 150, and heat dissipation electrode 151.

The module laminate 90 has main surfaces 90a and 90b facing each other. The main surface 90a is an example of a first main surface, while the main surface 90b is an example of a second main surface. In FIGS. 7 and 8, the module laminate 90 has a rectangular shape in a plan view but is not limited to this shape.

As the module laminate 90, a low temperature co-fired ceramics (LTCC) substrate or a high temperature co-fired ceramics (HTCC) substrate having a multilayer structure constituted by plural dielectric layers, a component-embedded board, a substrate having a redistribution layer (RDL), or a printed circuit board, for example, may be used. However, the module laminate 90 is not limited to these examples.

On the main surface 90a, an integrated circuit 91, duplexers 61 and 62, and resin member 95a are disposed.

The integrated circuit 91 is an example of a first integrated circuit and includes the power amplifiers 11 through 13. Within the integrated circuit 91, the sizes of the power amplifiers 11 and 12 are different from each other. In this example, the size of the power amplifier 12 is smaller than that of the power amplifier 11. The size of a power amplifier is proportional to the maximum gain and is dependent on the number of stages, the number of cells, or the number of fingers of a transistor. Accordingly, if the sizes of power amplifiers are different, the number of stages, the number of cells, or the number of fingers of a transistor of one power amplifier and that of the other power amplifier are different. The power amplifiers 11 and 12 may have the same size.

The integrated circuit 91 is made of at least one of gallium arsenide (GaAs), silicon-germanium (SiGe), and gallium nitride (GaN). Each of the power amplifiers 11 through 13 includes a bipolar transistor, such as a heterojunction bipolar transistor (HBT), as an amplifying element.

The integrated circuit 91 may be constituted by a CMOS (Complementary Metal Oxide Semiconductor), and more specifically, the integrated circuit 91 may be manufactured by a SOI (Silicon on Insulator) process. In this case, each of the power amplifiers 11 through 13 may include a field effect transistor (FET), such as a MOSFET (Metal-Oxide-Semiconductor Field Effect Transistor), as an amplifying element. The semiconductor material for the integrated circuit 91 is not limited to the above-described materials.

As the duplexers 61 and 62, any type of filter among surface acoustic wave (SAW) filters, bulk acoustic wave (BAW) filters, LC resonance filters, and dielectric filters, for example, may be used. The duplexers 61 and 62 are not limited to the above-described types of filters.

The resin member 95a covers the main surface 90a and the components disposed on the main surface 90a. The resin member 95a has a function of securing the reliability, such as the mechanical strength and the moisture resistance, of the components on the main surface 90a.

Within the module laminate 90, the transformer 21 and the transmission line 31 are disposed.

The input coil 211 and the output coil 212 of the transformer 21 are formed on different layers of the module laminate 90 by using planar wiring patterns. More specifically, the output coil 212 is disposed on a layer on the main surface 90a of the module laminate 90, while the input coil 211 is disposed on a layer within the module laminate 90. In a plan view of the module laminate 90, at least part of the input coil 211 matches at least part of the output coil 212.

The transmission line 31 is disposed within the module laminate 90 and is constituted by a planar wiring pattern. In FIG. 9, the transmission line 31 is located on a layer closer to the main surface 90b than the transformer 21 (input coil 211 and output coil 212) is.

On the main surface 90b, integrated circuits 92 and 93, plural post electrodes 150, heat dissipation electrode 151, and resin member 95b are disposed.

The integrated circuit 92 includes the low-noise amplifier 14 and the switches 51 and 53. The integrated circuit 93 is an example of a second integrated circuit and includes the switches 41 and 52 and the control circuit 71. Within the integrated circuit 93, the switch 41 is located at a position closer to the integrated circuit 91 than the control circuit 71 is.

The integrated circuits 92 and 93 are each constituted by a CMOS, and more specifically, they are manufactured by the SOI process. Each of the integrated circuits 92 and 93 may be made of at least one of GaAs, SiGe, and GaN.

The plural post electrodes 150 are plural external connection terminals including a ground terminal as well as the antenna connection terminal 100, external input terminal 110, and power supply terminal 130 shown in FIG. 1. Each of the post electrodes 150 vertically extends from the main surface 90b and passes through the resin member 95b, and one end of each of the post electrodes 150 reaches the surface of the resin member 95b. The post electrodes 150 are connected to an input/output terminal and/or a ground terminal, for example, on a mother substrate disposed in the negative-side direction of the z axis of the radio-frequency module 1M.

Instead of the post electrodes 150, plural bump electrodes may be included in the radio-frequency module 1M. In this case, the provision of the resin member 95b in the radio-frequency module 1M may be omitted.

The heat dissipation electrode 151 is an electrode for radiating heat generated in the power amplifiers 11 through 13 to the mother substrate (not shown). In a plan view, at least part of the heat dissipation electrode 151 matches at least part of the integrated circuit 91.

The resin member 95b covers the main surface 90b and the components disposed on the main surface 90b. The resin member 95b has a function of securing the reliability, such as the mechanical strength and the moisture resistance, of the components on the main surface 90b.

The shield electrode layer 96 is a metal thin film formed by sputtering, for example. The shield electrode layer 96 covers the top surface and the side surfaces of the resin member 95a, the side surfaces of the module laminate 90, and the side surfaces of the resin member 95b. The shield electrode layer 96 is set to a ground potential and contributes to preventing outside noise from entering the circuit components forming the radio-frequency module 1M.

The layout of the components of the radio-frequency module 1M shown in FIGS. 7 through 9 is an example and does not restrict the layout of the components. In one example, the integrated circuits 92 and 93 may be disposed on the main surface 90a. In another example, the provision of the resin members 95a and 95b and the shield electrode layer 96 in the radio-frequency module 1M may be omitted.

### [5.2 Power Amplifier Module 10M]

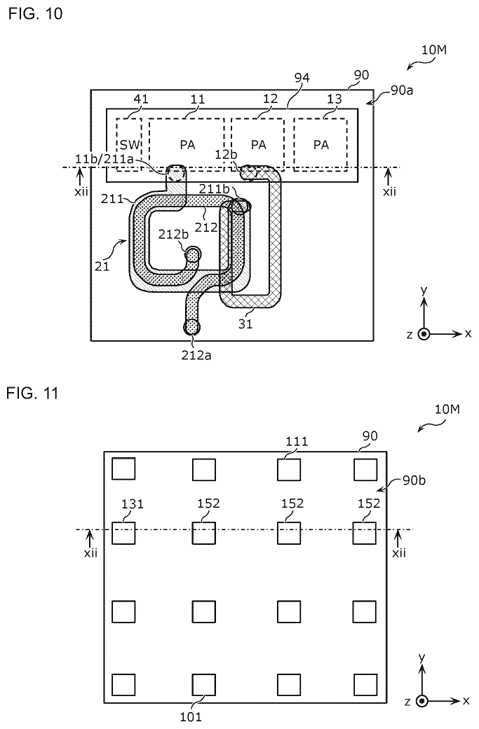

As an example of the power amplifier circuit 10 according to the above-described embodiment, a power amplifier module 10M will be discussed below with reference to FIGS. 10 through 12.

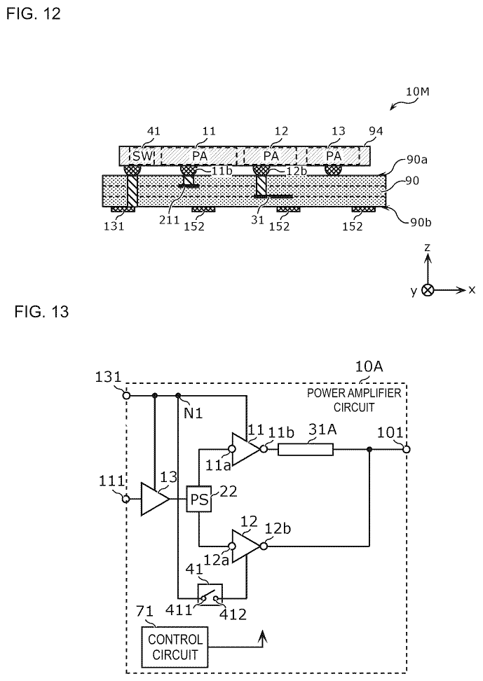

FIG. 10 is a plan view of the power amplifier module 10M according to the present example when the main surface 90a of the module laminate 90 and the inside of the module laminate 90 are seen through from the positive side of the z axis. FIG. 11 is a plan view of the power amplifier module 10M according to the present example when the main surface 90b of the module laminate 90 is seen through from the positive side of the z axis. FIG. 12 is a sectional view of the power amplifier module 10M according to the present example. The cross section of the power amplifier module 10M in FIG. 12 is a cross section taken along line xii-xii in FIGS. 10 and 11.

In addition to the plural circuit components included in the power amplifier circuit 10 shown in FIG. 1, the power amplifier module 10M includes the module laminate 90 and plural pad electrodes 152.

On the main surface 90a, an integrated circuit 94 is disposed. The integrated circuit 94 includes the power amplifiers 11 through 13 and the switch 41. Within the integrated circuit 94, the sizes of the power amplifiers 11 and 12 are different from each other. In this example, the size of the power amplifier 12 is smaller than that of the power amplifier 11. The power amplifiers 11 and 12 may have the same size. The integrated circuit 94 is made of at least one of GaAs, SiGe, and GaN. Each of the power amplifiers 11 through 13 includes a bipolar transistor, such as an HBT, as an amplifying element.

The integrated circuit 94 may be constituted by a CMOS, and more specifically, it may be manufactured by the SOI process. In this case, each of the power amplifiers 11 through 13 may include an FET, such as a MOSFET, as an amplifying element. The semiconductor material for the integrated circuit 94 is not limited to the above-described materials.

In a plan view, the switch 41 is closer to the power supply terminal 131 than the power amplifier 12 is. That is, within the integrated circuit 94, the switch 41 is disposed closer to the power supply terminal 131 than the power amplifier 12 is.

Within the module laminate 90, the transformer 21 and the transmission line 31 are disposed. The layout of the transformer 21 and the transmission line 31 is similar to that of the radio-frequency module 1M of the first example, and an explanation thereof will thus be omitted.

On the main surface 90b, the plural pad electrodes 152 are arranged. The pad electrodes 152 are plural external connection terminals including a ground terminal as well as the external output terminal 101, external input terminal 111, and power supply terminal 131 shown in FIG. 1. The pad electrodes 152 are connected to an input/output terminal and/or a ground terminal, for example, on the mother substrate disposed in the negative-side direction of the z axis of the power amplifier module 10M. Instead of the pad electrodes 152, plural bump electrodes or plural post electrodes may be included in the power amplifier module 10M.

The control circuit 71 is not shown in FIGS. 10 through 12. The control circuit 71 may be included in the power amplifier module 10M or the provision of the control circuit 71 may be omitted. If the control circuit 71 is included in the power amplifier module 10M, it may be disposed on the main surface 90a or be stacked on the integrated circuit 94. The switch 41 may be contained in an integrated circuit including the control circuit 71 instead of being contained in the integrated circuit 94 including the power amplifiers 11 through 13.

The layout of the components of the power amplifier module 10M shown in FIGS. 10 through 12 is an example and does not restrict the layout of the components. In one example, the power amplifier module 10M may include a resin member 95a and/or a resin member 95b and may include a shield electrode layer 96.

### [6 Advantages and Other Aspects]

As described above, a power amplifier circuit 10 according to the embodiment includes an external input terminal 111, an external output terminal 101, power amplifiers 11 and 12, a power supply terminal 131, and a switch 41. The power amplifier 11 has an input terminal 11a connected to the external input terminal 111 and an output terminal 11b connected to the external output terminal 101. The power amplifier 12 has an input terminal 12a connected to the external input terminal 111 and an output terminal 12b connected to the external output terminal 101. The power supply terminal 131 receives from a power supply circuit 5 a power supply voltage to be supplied to the power amplifiers 11 and 12. The switch 41 has a terminal 411 connected to the power supply terminal 131 and a terminal 412 connected to the power amplifier 12.

With this configuration, the switch 41, which is connected between the power supply terminal 131 and the power amplifier 12, can select whether to supply a power supply voltage to the power amplifier 12. When output power is low, the switch 41 is turned OFF, and when output power is high, the switch 41 is turned ON. With this operation, the power amplifier 12 can operate similarly to a peak amplifier in a Doherty amplifier, thereby improving the efficiency. If a power supply voltage of multiple discrete voltage levels is supplied from the power supply circuit 5 to the power supply terminal 131, the switch 41 can be changed between ON and OFF for the same voltage level. As a result, while the efficiency is being improved by changing the level of the power supply voltage, a decrease in efficiency caused by discrete voltage levels of the power supply voltage can be regulated by changing the ON/OFF states of the switch 41.

Additionally, for example, in the power amplifier circuit 10 according to the embodiment, the sizes of the power amplifiers 11 and 12 may be different from each other.

With this configuration, compared with the configuration in which the sizes of the power amplifiers 11 and 12 are the same, the design flexibility regarding a difference in efficiency-peak output power (regarding back-off) caused by switching the ON/OFF states of the power amplifier 12, namely, by changing the switch 41 between ON and OFF, can be enhanced. It is thus possible to more effectively regulate a decrease in efficiency caused by discrete voltage levels of the power supply voltage.

Additionally, for example, in the power amplifier circuit 10 according to the embodiment, the size of the power amplifier 12 may be smaller than that of the power amplifier 11.

With this configuration, the back-off, which is caused by changing the ON/OFF states of the switch 41, can be reduced compared with the configuration in which the sizes of the power amplifiers 11 and 12 are the same. It is thus possible to more effectively regulate a decrease in efficiency caused by discrete voltage levels of the power supply voltage.

Furthermore, for example, in the power amplifier circuit 10 according to the embodiment, the power supply voltage received by the power supply terminal 131 from the power supply circuit 5 may be variable to multiple discrete voltage levels within one frame of a radio-frequency signal.

With this configuration, even when the level of the power supply voltage is discretely varied at high speed within one frame, the ON/OFF states of the power amplifier 12 can follow a change in the voltage level because the switch 41 selects whether to supply the power supply voltage to the power amplifier 12.

For example, the power amplifier circuit 10 according to the embodiment may also include a transformer 21 and a transmission line 31. The transformer 21 includes an input coil 211 and an output coil 212. The transmission line 31 is connected to the output terminal 12b of the power amplifier 12. One end 211a of the input coil 211 may be connected to the output terminal 11b of the power amplifier 11. The other end 211b of the input coil 211 may be connected to the output terminal 12b of the power amplifier 12 via the transmission line 31. One end 212a of the output coil 212 may be connected to the external output terminal 101. The other end 212b of the output coil 212 may be connected to a ground.

With this configuration, the voltage of a radio-frequency signal amplified by the power amplifier 11 and the voltage of a radio-frequency signal amplified by the power amplifier 12 can be combined with each other.

Moreover, for example, in the power amplifier circuit 10 according to the embodiment, when a power supply voltage of a first voltage level (Vcc1) is supplied to the power supply terminal 131 and when a first control signal indicating that the power amplifier 12 is to be used to amplify a radio-frequency signal is received, the switch 41 may connect the terminal 411 to the terminal 412. When a power supply voltage of the first voltage level (Vcc1) is supplied to the power supply terminal 131 and when a second control signal indicating that the power amplifier 12 is not to be used to amplify a radio-frequency signal is received, the switch 41 may prevent the connection of the terminal 411 to the terminal 412. When a power supply voltage of a second voltage level (Vcc2), which is lower than the first voltage level (Vcc1), is supplied to the power supply terminal 131 and when the first control signal is received, the switch 41 may connect the terminal 411 to the terminal 412.

With this configuration, in a case in which a power supply voltage of the first voltage level (Vcc1) and a power supply voltage of the second voltage level (Vcc2) can be supplied, when a power supply voltage of the first voltage level (Vcc1) is supplied, the ON/OFF states of the switch 41 can be switched by a control signal. This can improve the efficiency with the use of the two discrete voltage levels and can also regulate a decrease in efficiency, which is caused by maintaining the first voltage level (Vcc1) even with a change in the envelope value.

Additionally, for example, in the power amplifier circuit 10 according to the embodiment, when a power supply voltage of the first voltage level (Vcc1) is supplied to the power supply terminal 131 and when the second control signal indicating that the power amplifier 12 is not to be used to amplify a radio-frequency signal is received, the switch 41 may prevent the connection of the terminal 411 to the terminal 412. When a power supply voltage of the second voltage level (Vcc2), which is lower than the first voltage level (Vcc1), is supplied to the power supply terminal 131 and when the first control signal indicating that the power amplifier 12 is to be used to amplify a radio-frequency signal is received, the switch 41 may connect the terminal 411 to the terminal 412. When a power supply voltage of the second voltage level (Vcc2) is supplied to the power supply terminal 131 and when the second control signal is received, the switch 41 may prevent the connection of the terminal 411 to the terminal 412.

With this configuration, in a case in which a power supply voltage of the first voltage level (Vcc1) and a power supply voltage of the second voltage level (Vcc2) can be supplied, when a power supply voltage of the second voltage level (Vcc2) is supplied, the ON/OFF states of the switch 41 can be switched by a control signal. This can improve the efficiency with the use of the two discrete voltage levels and can also regulate a decrease in efficiency, which is caused by maintaining the second voltage level (Vcc2) even with a change in the envelope value.

For example, a radio-frequency module 1M according to an example of the embodiment may include a module laminate 90 having main surfaces 90a and 90b facing each other. An integrated circuit 91 including the power amplifiers 11 and 12 may be disposed in or on the main surface 90a. An integrated circuit 93 and the power supply terminal 130 may be disposed in or on the main surface 90b. The integrated circuit 93 includes the switch 41 and a control circuit 71 that controls the power amplifiers 11 and 12.

With this configuration, the switch 41 and the control circuit 71 can be integrated into the single integrated circuit 93, thereby enhancing the miniaturization of the radio-frequency module 1M.

Furthermore, for example, in the radio-frequency module 1M according to the example of the embodiment, within the integrated circuit 93, the switch 41 may be disposed at a position closer to the integrated circuit 91 than the control circuit 71 is.

This can shorten the length of a line connecting the switch 41 and the power amplifier 12, thereby reducing loss in the power supply voltage line.

For example, a power amplifier module 10M according to an example of the embodiment may include a module laminate 90 in or on which an integrated circuit 94 and the power supply terminal 131 are disposed. The integrated circuit 94 includes the power amplifiers 11 and 12 and the switch 41. Within the integrated circuit 94, the switch 41 may be disposed at a position closer to the power supply terminal 131 than the power amplifier 12 is.

This can shorten the length of a line connecting the switch 41 and the power supply terminal 131, thereby reducing loss in the power supply voltage line.

Moreover, for example, in the power amplifier module 10M according to the example of the embodiment, the module laminate 90 may have main surfaces 90a and 90b facing each other. The integrated circuit 94 may be disposed in or on the main surface 90a. The power supply terminal 131 may be disposed in or on the main surface 90b. In a plan view of the module laminate 90, at least part of the switch 41 may match at least part of the power supply terminal 131.

This can further shorten the length of the line connecting the switch 41 and the power supply terminal 131, thereby further reducing loss in the power supply voltage line.

In a power amplification method according to the embodiment, when a power supply voltage of a first voltage level (Vcc1) is supplied to the power supply terminal 131 and when a first control signal indicating that the power amplifier 12 is to be used to amplify a radio-frequency signal is received, a radio-frequency signal is amplified with the power supply voltage of the first voltage level (Vcc1) by using the power amplifiers 11 and 12. When a power supply voltage of the first voltage level (Vcc1) is supplied to the power supply terminal 131 and when a second control signal indicating that the power amplifier 12 is not to be used to amplify a radio-frequency signal is received, a radio-frequency signal is amplified with the power supply voltage of the first voltage level (Vcc1) by using the power amplifier 11. When a power supply voltage of a second voltage level (Vcc2), which is lower than the first voltage level (Vcc1), is supplied to the power supply terminal 131 and when the first control signal is received, a radio-frequency signal is amplified with the power supply voltage of the second voltage level (Vcc2) by using the power amplifiers 11 and 12.

With this configuration, in a case in which a power supply voltage of the first voltage level (Vcc1) and a power supply voltage of the second voltage level (Vcc2) can be supplied, when a power supply voltage of the first voltage level (Vcc1) is supplied, the ON/OFF states of the power amplifier 12 can be switched in accordance with a control signal. This can improve the efficiency with the use of the two discrete voltage levels and can also regulate a decrease in efficiency, which is caused by maintaining the first voltage level (Vcc1) even with a change in the envelope value.

Additionally, for example, in the power amplification method according to the embodiment, the power amplifier 12 may be connected to the power supply terminal 131 via the switch 41. The switch 41 may connect the power amplifier 12 to the power supply terminal 131 when the first control signal is received. The switch 41 may prevent the connection of the power amplifier 12 to the power supply terminal 131 when the second control signal is received.

With this configuration, as a result of the switch 41 selecting whether to connect the power amplifier 12 to the power supply terminal 131, the ON/OFF states of the power amplifier 12 can be switched at high speed.

In a power amplification method according to the embodiment, when a power supply voltage of the first voltage level (Vcc1) is supplied to the power supply terminal 131 and when the second control signal indicating that the power amplifier 12 is not to be used to amplify a radio-frequency signal is received, a radio-frequency signal is amplified with the power supply voltage of the first voltage level (Vcc1) by using the power amplifier 11. When a power supply voltage of the second voltage level (Vcc2), which is lower than the first voltage level (Vcc1), is supplied to the power supply terminal 131 and when the first control signal indicating that the power amplifier 12 is to be used to amplify a radio-frequency signal is received, a radio-frequency signal is amplified with the power supply voltage of the second voltage level (Vcc2) by using the power amplifiers 11 and 12. When a power supply voltage of the second voltage level (Vcc2) is supplied to the power supply terminal 131 and when the second control signal is received, a radio-frequency signal is amplified with the power supply voltage of the second voltage level (Vcc2) by using the power amplifier 11.

With this configuration, in a case in which a power supply voltage of the first voltage level (Vcc1) and a power supply voltage of the second voltage level (Vcc2) can be supplied, when a power supply voltage of the second voltage level (Vcc2) is supplied, the ON/OFF states of the power amplifier 12 can be switched in accordance with a control signal. This can improve the efficiency with the use of the two discrete voltage levels and can also regulate a decrease in efficiency, which is caused by maintaining the second voltage level (Vcc2) even with a change in the envelope value.

Additionally, for example, in the power amplification method according to the embodiment, the power amplifier 12 may be connected to the power supply terminal 131 via the switch 41. The switch 41 may connect the power amplifier 12 to the power supply terminal 131 when the first control signal is received. The switch 41 may prevent the connection of the power amplifier 12 to the power supply terminal 131 when the second control signal is received.

With this configuration, as a result of the switch 41 selecting whether to connect the power amplifier 12 to the power supply terminal 131, the use of the power amplifiers 11 and 12 and the use of the power amplifier 12 can be switched at high speed.

### Modified Examples

The power amplifier circuit, radio-frequency circuit, communication device, and power amplification method according to the present disclosure have been discussed above through illustration of the embodiment. However, the power amplifier circuit, radio-frequency circuit, communication device, and power amplification method according to the disclosure are not restricted to the above-described embodiment. Other embodiments implemented by combining certain elements in the above-described embodiment and modified examples obtained by making various modifications to the above-described embodiment by those skilled in the art without departing from the scope and spirit of the invention are also encompassed as part of the invention. Various types of equipment integrating the above-described radio-frequency circuit are also encompassed by the disclosed teachings.

For example, in the circuit configurations of the power amplifier circuit, radio-frequency circuit, and communication device according to the above-described embodiment, another circuit element and another wiring may be inserted onto a path connecting circuit elements and/or onto a path connecting signal paths illustrated in the drawings. For instance, an impedance matching circuit may be inserted between the transmit filter 61T and the power amplifier circuit 10 and/or between the duplexer 61 and the antenna connection terminal 100. Likewise, an impedance matching circuit may be inserted between another two circuit elements. The impedance matching circuit can be constituted by an inductor and/or a capacitor, for example.

The power amplification method according to the above-described embodiment is applied to the digital ET mode. However, the power amplification method may be applied to another mode. For example, the power amplification method may be applied to the APT mode in which the voltage level is switched in a shorter period (subframe, for example). In this case, too, the efficiency can be improved by changing the level of a power supply voltage, and a decrease in efficiency caused by discrete voltage levels of the power supply voltage can also be regulated.

In the above-described embodiment, the power amplifier circuit includes a transformer. However, the power amplifier circuit is not restricted to this configuration. For instance, as in a power amplifier circuit 10A according to a modified example illustrated in FIG. 13, the provision of a transformer in a power amplifier circuit may be omitted. In this case, a transmission line 31A included in the power amplifier circuit 10A may be connected between the output terminal 11b of the power amplifier 11 and the external output terminal 101.

In this manner, the power amplifier circuit 10A according to the modified example may also include the transmission line 31A connected between the output terminal 11b of the power amplifier 11 and the external output terminal 101.

With this configuration, the current of a radio-frequency signal amplified by the power amplifier 11 and the current of a radio-frequency signal amplified by the power amplifier 12 can be combined with each other.

### INDUSTRIAL APPLICABILITY

The present disclosure can be widely used in communication equipment, such as mobile phones, as a power amplifier circuit or a radio-frequency circuit disposed in a multiband-support front-end section.

### REFERENCE SIGNS LIST

1 radio-frequency circuit
1M radio-frequency module
2 antenna
3 RFIC
4 BBIC
5 power supply circuit
6 communication device
10, 10A power amplifier circuit
10M power amplifier module
11, 12, 13 power amplifier
11a, 12a input terminal
11b, 12b output terminal
14 low-noise amplifier
21 transformer
22 phase shifter
31, 31A transmission line
41, 51, 52, 53 switch
61, 62 duplexer
61R, 62R receive filter
61T, 62T transmit filter
71 control circuit
90 module laminate
90a, 90b main surface
91, 92, 93, 94 integrated circuit
95a, 95b resin member
96 shield electrode layer
100 antenna connection terminal
101 external output terminal
110, 111 external input terminal
120, 121 control terminal
130, 131 power supply terminal
150 post electrode
151 heat dissipation electrode
152 pad electrode
211 input coil
211a one end of input coil
211b the other end of input coil
212 output coil
212a one end of output coil
212b the other end of output coil
411, 412, 511, 512, 513, 521, 522, 523, 531, 532, 533 terminal

1. A power amplifier circuit comprising:
an external input terminal and an external output terminal;
a first power amplifier having a first input terminal and a first output terminal, the first input terminal being connected to the external input terminal, the first output terminal being connected to the external output terminal;
a second power amplifier having a second input terminal and a second output terminal, the second input terminal being connected to the external input terminal, the second output terminal being connected to the external output terminal;
a power supply terminal that receives from a power supply circuit a power supply voltage that is supplied to the first power amplifier and controllably supplied to the second power amplifier; and
a switch having a first terminal and a second terminal, the first terminal being connected to the power supply terminal, the second terminal being connected to the second power amplifier.

2. The power amplifier circuit according to claim 1, wherein a size of the first power amplifier is different than a size of the second power amplifier.

3. The power amplifier circuit according to claim 2, wherein the size of the second power amplifier is smaller than the size of the first power amplifier.

4. The power amplifier circuit according to claim 1, wherein the power supply voltage received by the power supply terminal from the power supply circuit varies between multiple discrete voltage levels within one frame of a radio-frequency signal.

5. The power amplifier circuit according to claim 1, further comprising:
a transformer including an input coil and an output coil; and
a transmission line connected to the second output terminal of the second power amplifier, wherein
one end of the input coil is connected to the first output terminal of the first power amplifier,
another end of the input coil is connected to the second output terminal of the second power amplifier via the transmission line,
one end of the output coil is connected to the external output terminal, and
another end of the output coil is connected to a ground.

6. The power amplifier circuit according to claim 1, further comprising:
a transmission line connected between the first output terminal of the first power amplifier and the external output terminal.

7. The power amplifier circuit according to claim 1, wherein:
under a condition in which a power supply voltage of a first voltage level is supplied to the power supply terminal and a first control signal indicating that the second power amplifier is to be used to amplify a radio-frequency signal is received, the switch connects the first terminal to the second terminal;
under another condition in which the power supply voltage of the first voltage level is supplied to the power supply terminal and a second control signal indicating that the second power amplifier is not to be used to amplify a radio-frequency signal is received, the switch does not connect the first terminal to the second terminal; and
under a third condition in which a power supply voltage of a second voltage level, the second voltage level being lower than the first voltage level, is supplied to the power supply terminal and the first control signal is received, the switch connects the first terminal to the second terminal.

8. The power amplifier circuit according to claim 1, wherein:
under a condition in which a power supply voltage of a first voltage level is supplied to the power supply terminal and a second control signal is received indicating that the second power amplifier is not to be used to amplify a radio-frequency signal, the switch does not connect the first terminal to the second terminal;
under another condition in which a power supply voltage of a second voltage level, the second voltage level being lower than the first voltage level, is supplied to the power supply terminal and a first control signal indicating that the second power amplifier is to be used to amplify a radio-frequency signal is received, the switch connects the first terminal to the second terminal; and
under a third condition in which the power supply voltage of the second voltage level is supplied to the power supply terminal and the second control signal is received, the switch does not connect the first terminal to the second terminal.

9. The power amplifier circuit according to claim 1, further comprising:
a module laminate having first and second main surfaces facing each other, wherein
a first integrated circuit including the first power amplifier and the second power amplifier is disposed on the first main surface, and
a second integrated circuit and the power supply terminal are disposed on the second main surface, the second integrated circuit including the switch, and a control circuit that controls the first and second power amplifiers.

10. The power amplifier circuit according to claim 9, wherein, within the second integrated circuit, the switch is disposed at a position closer to the first integrated circuit than the control circuit.

11. The power amplifier circuit according to claim 1, further comprising:
a module laminate on which an integrated circuit and the power supply terminal are disposed, the integrated circuit including the first power amplifier, the second power amplifier, and the switch,
wherein, within the integrated circuit, the switch is disposed at a position closer to the power supply terminal than the second power amplifier is.

12. The power amplifier circuit according to claim 11, wherein:
the module laminate has a first main surface that faces a second main surface;
the integrated circuit is disposed on the first main surface;
the power supply terminal is disposed on the second main surface; and
in a plan view of the module laminate, at least part of the switch overlaps at least part of the power supply terminal.

13. The power amplifier circuit according to claim 2, further comprising:
a module laminate on which an integrated circuit and the power supply terminal are disposed, the integrated circuit including the first power amplifier, the second power amplifier, and the switch,
wherein, within the integrated circuit, the switch is disposed at a position closer to the power supply terminal than the second power amplifier is.

14. The power amplifier circuit according to claim 3, further comprising:
a module laminate on which an integrated circuit and the power supply terminal are disposed, the integrated circuit including the first power amplifier, the second power amplifier, and the switch,
wherein, within the integrated circuit, the switch is disposed at a position closer to the power supply terminal than the second power amplifier is.

15. The power amplifier circuit according to claim 4, further comprising:
a module laminate on which an integrated circuit and the power supply terminal are disposed, the integrated circuit including the first power amplifier, the second power amplifier, and the switch,
wherein, within the integrated circuit, the switch is disposed at a position closer to the power supply terminal than the second power amplifier is.

16. The power amplifier circuit according to claim 5, further comprising:
a module laminate on which an integrated circuit and the power supply terminal are disposed, the integrated circuit including the first power amplifier, the second power amplifier, and the switch,
wherein, within the integrated circuit, the switch is disposed at a position closer to the power supply terminal than the second power amplifier is.

17. A power amplification method comprising:
amplifying a radio-frequency signal with a power supply voltage of a first voltage level by using a first power amplifier and a second power amplifiers under a condition a power supply voltage of the first voltage level is supplied to a power supply terminal and in response to receiving a first control signal indicating that the second power amplifier is also to be used to amplify the radio-frequency signal;
amplifying the radio-frequency signal with the power supply voltage of the first voltage level by using the first power amplifier under the condition the power supply voltage of the first voltage level is supplied to the power supply terminal and in response to receiving a second control signal indicating that the second power amplifier is not to be used to amplify the radio-frequency signal; and
amplifying the radio-frequency signal with a power supply voltage of a second voltage level, the second voltage level being lower than the first voltage level, by using the first power amplifier and the second power amplifier under another condition that the power supply voltage of the second voltage level is supplied to the power supply terminal and in response to receiving the first control signal.

18. The power amplification method according to claim 17, wherein:
the second power amplifier is connected to the power supply terminal via a switch; and further comprising
connecting the second power amplifier to the power supply terminal via the switch in response to receiving the first control signal; and
not connecting the second power amplifier to the power supply terminal with the switch in response to receiving the second control signal.

19. A power amplification method comprising:
amplifying a radio-frequency signal with a power supply voltage of a first voltage level by using a first power amplifier under a condition the power supply voltage of the first voltage level is supplied to a power supply terminal and in response to receiving a second control signal indicating that a second power amplifier is not to be used to amplify a radio-frequency signal;
amplifying a radio-frequency signal with a power supply voltage of a second voltage level, the second voltage level being lower than the first voltage level, by using the first and second power amplifiers under another condition that a power supply voltage of the second voltage level is supplied to the power supply terminal and in response to receiving a first control signal indicating that the second power amplifier is to be used to amplify the radio-frequency signal; and
amplifying the radio-frequency signal with a power supply voltage of the second voltage level by using the first power amplifier under a third condition of a power supply voltage of the second voltage level being supplied to the power supply terminal and in response to receiving the second control signal.

20. The power amplification method according to claim 19, wherein:
the second power amplifier is connected to the power supply terminal via a switch; and further comprising
connecting the second power amplifier to the power supply terminal with the switch and in response to receiving the first control signal; and
not connecting the second power amplifier to the power supply terminal via the switch in response to receiving the second control signal.
